(19) United States
(12) Patent Application Publication
(10) Pub. No.: US 2025/0324716 A1
(43) Pub. Date: Oct. 16, 2025

(54) SEMICONDUCTOR DEVICE AND METHOD FOR MANUFACTURING SEMICONDUCTOR DEVICE

(71) Applicant: Renesas Electronics Corporation, Tokyo (JP)

(72) Inventors: Takeshi KISHIDA, Tokyo (JP); Yoshito NAKAZAWA, Tokyo (JP)

(21) Appl. No.: 19/070,767

(22) Filed: Mar. 5, 2025

(30) Foreign Application Priority Data
Apr. 15, 2024 (JP) 2024-065209

(51) Int. Cl. H10D 64/27; H10D 30/01; H10D 30/66; H10D 62/40; H10D 64/00; H10D 84/83

(52) U.S. Cl. CPC H10D 64/518; H10D 30/0297; H10D 30/668; H10D 64/117; H10D 62/405; H10D 64/513; H10D 84/839

(57) ABSTRACT

Provided is a semiconductor device including a trench formed in a first main surface of a semiconductor chip, in which the trench has a portion extending in a first direction and a portion extending in a second direction different from the first direction in a continuous manner in plan view. The trench has a portion extending in a third direction different from the first direction and the second direction, in which the portion extending in the third direction is located between the portion extending in the first direction and the portion extending in the second direction in plan view, the portion extending in the first direction intersects the portion extending in the third direction at an obtuse angle, and the portion extending in the second direction intersects the portion extending in the third direction at an obtuse angle.

### CROSS-REFERENCE TO RELATED APPLICATIONS

The disclosure of Japanese Patent Application No. 2024-065209 filed on Apr. 15, 2024 including the specification, drawings and abstract is incorporated herein by reference in its entirety.

### BACKGROUND

The present disclosure relates to a semiconductor device and a method for manufacturing the semiconductor device.

There are disclosed techniques listed below.

[Patent Document 1] Japanese Unexamined Patent Application Publication No. 2024-1723

Patent Document 1 describes a power MOSFET (Metal Oxide Semiconductor Field Effect Transistor) in which a field plate electrode and a gate electrode are formed in a trench.

### SUMMARY

However, since trenches are arranged in parallel in one direction on a semiconductor chip, there is a problem in that a semiconductor wafer on which a plurality of the semiconductor chips are formed warps. Therefore, an object of the present disclosure is to provide a semiconductor device in which trenches respectively extending in a first direction and a second direction in a continuous manner are formed in a semiconductor chip so as to control warpage.

Other problems and novel features will become apparent from the description of the present specification and the accompanying drawings.

According to one embodiment, a semiconductor device includes a trench having a portion extending in a first direction and a portion extending in a second direction in a continuous manner in plan view.

According to the above embodiment, it is possible to provide a semiconductor device capable of controlling warpage of a semiconductor chip and eventually a semiconductor wafer.

### BRIEF DESCRIPTION OF THE DRAWINGS

FIG. 1 is a plan view illustrating a related semiconductor device.

FIG. 2 is an enlarged plan view illustrating a main part of the related semiconductor device.

FIG. 3 is an enlarged plan view illustrating the main part of the related semiconductor device.

FIG. 4 is a cross-sectional view illustrating the related semiconductor device.

FIG. 5 is a cross-sectional view illustrating the related semiconductor device.

FIG. 6 is a layout of trenches of the related semiconductor device.

FIG. 7 is a view illustrating wafer warpage of the related semiconductor device.

FIG. 8 is a layout of trenches of a semiconductor device according to an embodiment.

### DETAILED DESCRIPTION

### Embodiments

Hereinafter, embodiments of the present invention will be described with reference to the drawings. However, the invention according to the claims is not limited to the following embodiments. In addition, all the configurations described in the embodiments are not essential means for solving the problem. For clarity of description, the following description and drawings are omitted and simplified as appropriate. In the drawings, the same elements are denoted by the same reference numerals, and redundant description is omitted as necessary.

The X direction, the Y direction, and the Z direction described in the present application intersect each other and are orthogonal to each other. In the present application, the Z direction will be described as a vertical direction, a height direction, or a thickness direction of a certain structure. In addition, the expression such as “plan view” or “plan view” used in the present application means that a surface constituted by the X direction and the Y direction is a “plane” and this “plane” is viewed from the Z direction.

### Description of Configuration and Problem of Related Semiconductor Device

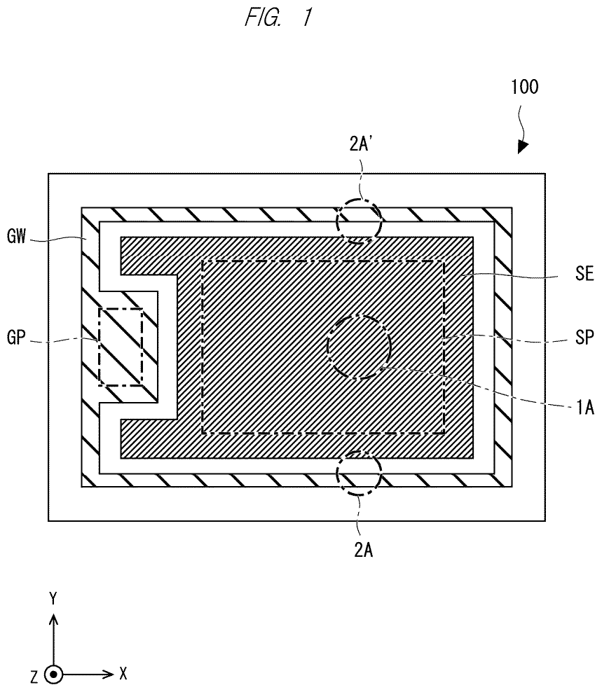

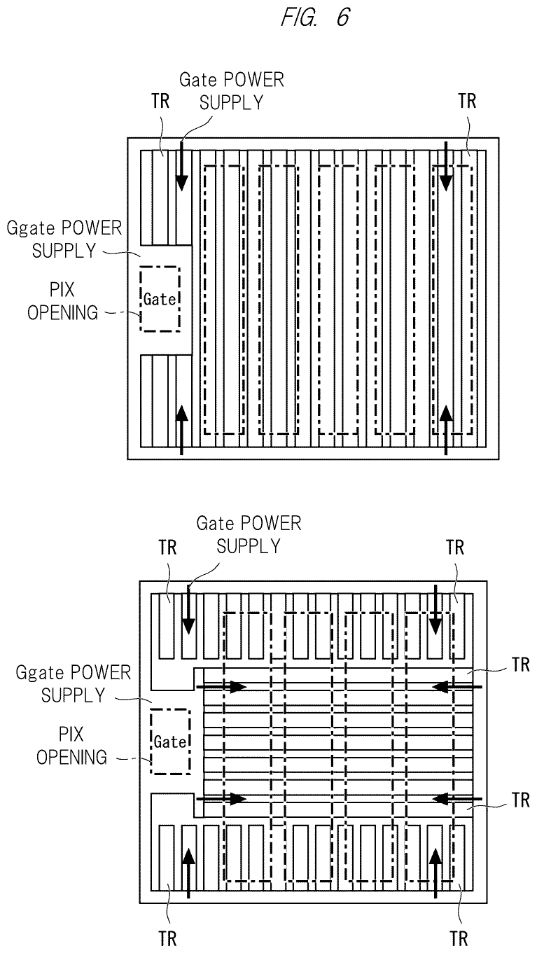

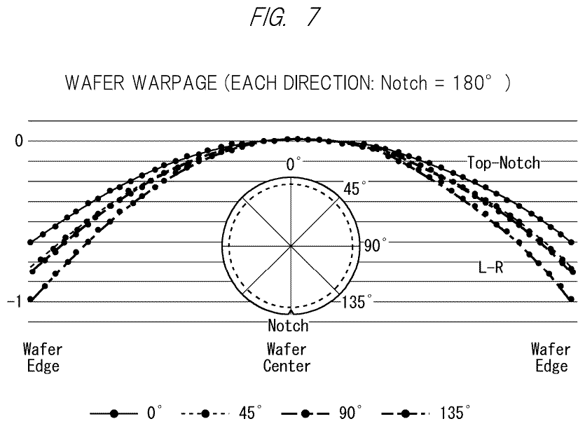

A related semiconductor device 100 will be described below with reference to FIGS. 1 to 5. Further, a problem of the related semiconductor device will be described with reference to FIGS. 6 and 7. The semiconductor device 100 includes a MOSFET having a trench gate structure as a semiconductor element. In particular, the relevant MOSFET has a split-gate structure including a gate electrode GE and a field plate electrode FP.

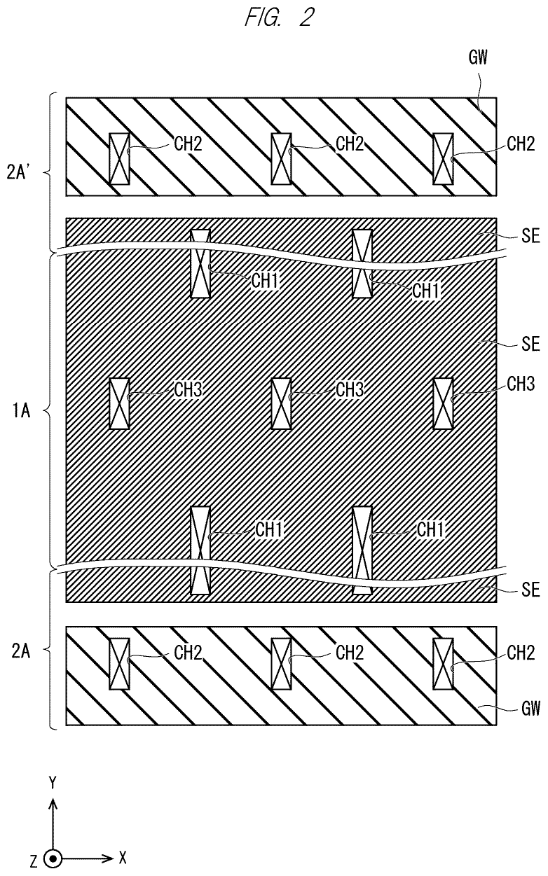

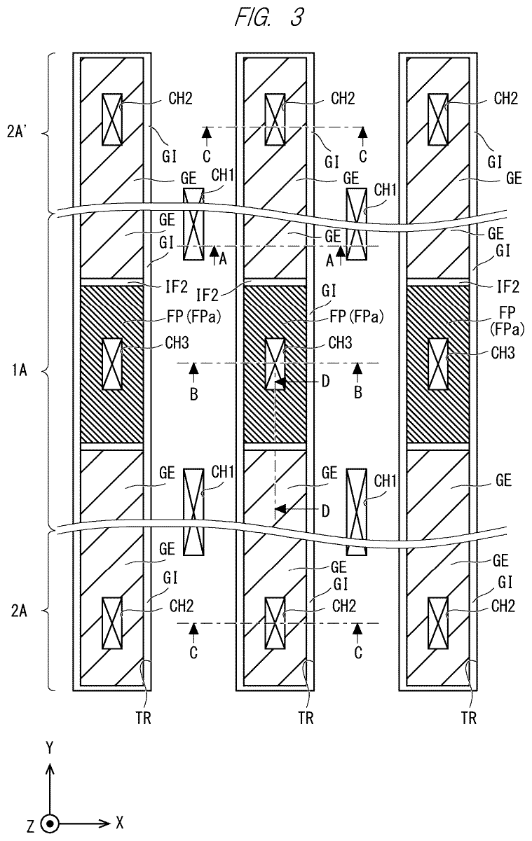

FIG. 1 is a plan view of a semiconductor chip which is the semiconductor device 100. FIG. 1 mainly illustrates a wiring pattern formed on a semiconductor substrate SUB. FIG. 2 is an enlarged plan view of a main part of FIG. 1. FIG. 3 illustrates a structure below FIG. 2, and illustrates a structure of a trench gate formed in the semiconductor substrate SUB.

As illustrated in FIG. 1, most of the semiconductor device 100 is covered with a source electrode (fixed potential supply wiring) SE. A gate wiring GW is provided along the outer periphery of the semiconductor device 100 and surrounds a source electrode SE in plan view. Although not illustrated here, the source electrode SE and the gate wiring GW are covered with a protective film such as a polyimide film. An opening is provided in a part of the protective film, and the source electrode SE and the gate wiring GW exposed through the opening become a source pad SP and a gate pad GP. By connecting an external connection member such as wire bonding or a clip (copper plate) on the source pad SP and the gate pad GP, the semiconductor device 100 is electrically connected to another semiconductor chip, a wiring board, or the like.

In addition, the semiconductor device 100 includes a region 1A and regions 2A and 2A′ surrounding the region 1A in plan view. The region 1A is a cell region in which main semiconductor elements such as a plurality of MOSFETs are formed. The regions 2A and 2A′ are outer peripheral regions used for connecting the gate wiring GW to the gate electrode GE.

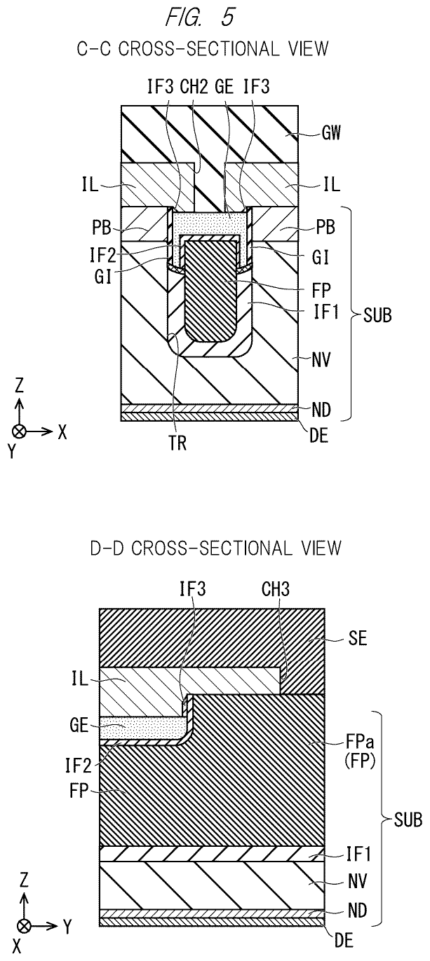

A positional relationship of holes CH1 to CH3 illustrated in FIG. 3 coincides with a positional relationship of holes CH1 to CH3 illustrated in FIG. 2. Note that the structure of the region 2A′ is obtained by inverting the structure of the region 2A on the drawing. Therefore, as in the C-C cross section in FIG. 5, the cross-sectional structure of the region 2A′ is similar to the cross-sectional structure of the region 2A.

As illustrated in FIG. 3, a plurality of trenches TR extend in the Y direction and are adjacent to each other in the X direction. The width of each of the trenches TR in the X direction is, for example, 1.5 μm or more and 1.8 μm or less.

Inside the trench TR, a field plate (fixed potential electrode) electrode FP is formed below the trench TR, and the gate electrode GE is formed above the trench TR. Therefore, in FIG. 3, the gate electrode GE is exposed. The field plate electrode FP and the gate electrode GE extend in the Y direction along the trench TR.

A part of the field plate electrode FP forms a contact portion FPa. The field plate electrode FP constituting the contact portion FPa is formed not only below the trench TR but also above the trench TR inside the trench TR in the region 1A. Therefore, in FIG. 3, the contact portion FPa is exposed.

The contact portion FPa divides the gate electrode GE into a region 2A side and a region 2A′ side.

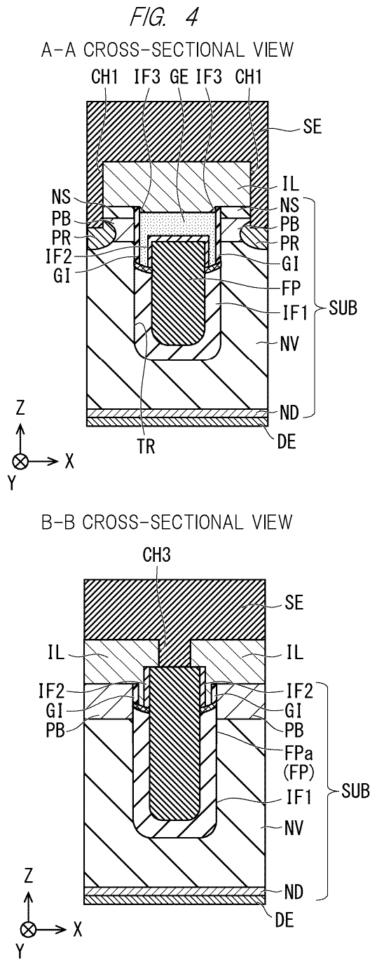

Hereinafter, a cross-sectional structure of the semiconductor device 100 will be described with reference to FIGS. 4 and 5. FIG. 4 is a cross-sectional view taken along lines A-A and B-B illustrated in FIG. 3. FIG. 5 is a cross-sectional view taken along lines C-C and D-D illustrated in FIG. 3.

First, a basic structure of the MOSFET will be described with reference to an A-A cross section in FIG. 4. The semiconductor device 100 includes a semiconductor substrate SUB having an upper surface and a lower surface. The semiconductor substrate SUB has drift region NV of n-type having a low concentration. Here, the n-type semiconductor substrate SUB itself constitutes the drift region NV. The drift region NV may be an n-type semiconductor layer grown on an n-type silicon substrate while introducing phosphorus (P) by an epitaxial growth method. In the present application, a stacked body including such an n-type silicon substrate and an n-type semiconductor layer will also be described as the semiconductor substrate SUB.

In the semiconductor substrate SUB, a plurality of trenches TR1 reaching a predetermined depth from the upper surface of the semiconductor substrate SUB are formed. The depth of each trench is, for example, 5 μm or more and 7 μm or less. Inside the trench TR, the field plate electrode FP is formed below the trench TR via an insulating film IF1. The position of the upper surface of the insulating film IF1 is lower than the position of the upper surface of the field plate electrode FP. An insulating film IF2 is formed on the upper surface and the side surface of the field plate electrode FP exposed from the insulating film IF1. A gate insulating film GI is formed on the semiconductor substrate SUB in the trench TR.

Inside the trench TR, the gate electrode GE is formed above the trench TR. The gate electrode GE is electrically insulated from the field plate electrode FP by the insulating film IF2, and is electrically insulated from the semiconductor substrate SUB by the gate insulating film GI. The gate electrode GE is also formed between the field plate electrode FP exposed from the insulating film IF1 and the semiconductor substrate SUB via the gate insulating film GI and the insulating film IF2.

The upper surface of the gate electrode GE is slightly recessed from the upper surface of the semiconductor substrate SUB. An insulating film IF3 is formed on the upper surface of a part of the gate electrode GE so as to be in contact with the gate insulating film GI.

The gate electrode GE and the field plate electrode FP are made of, for example, a polycrystalline silicon film into which n-type impurities are introduced. The insulating film IF1, the insulating film IF2, the insulating film IF3, and the gate insulating film GI are made of, for example, a silicon oxide film.

A thickness of the insulating film IF1 is larger than a thickness of each of the insulating film IF2, the insulating film IF3, and the gate insulating film GI. The thickness of the insulating film IF1 is, for example, 400 nm or more and 600 nm or less. The thickness of each of the insulating film IF2 and the gate insulating film is, for example, 50 nm or more and 80 nm or less. The thickness of the insulating film IF3 is, for example, 30 nm or more and 80 nm or less.

On the upper surface side of the semiconductor substrate SUB, a p-type body region PB is formed on the semiconductor substrate SUB so as to be shallower than the trench TR. In the body region PB, an n-type source region NS is formed. The source region NS has an impurity concentration higher than that of a drift region NV.

On the lower surface side of the semiconductor substrate SUB, an n-type drain region ND is formed in the semiconductor substrate SUB. The drain region ND has an impurity concentration higher than that of the drift region NV. A drain electrode DE is formed under the lower surface of the semiconductor substrate SUB. The drain electrode DE is made of, for example, a single-layer metal film such as an aluminum film, a titanium film, a nickel film, a gold film, or a silver film, or a laminated film obtained by appropriately laminating the above-mentioned metal films.

On the upper surface of the semiconductor substrate SUB, an interlayer insulating film IL is formed so as to cover the trench TR. The interlayer insulating film IL is made of, for example, a silicon oxide film. The thickness of the interlayer insulating film IL is, for example, 700 nm or more and 900 nm or less. Note that the interlayer insulating film IL may be a laminated film of a thin silicon oxide film and a thick silicon oxide film (a phospho silicate glass (PSG) film) containing phosphorus.

Holes CH1 are formed in the interlayer insulating film IL, the source region NS, and the body region PB. In the bottom portion of the hole CH1, a high concentration region PR is formed in the body region PB. The high concentration region PR has a higher impurity concentration than that of the body region PB.

The source electrode SE is formed on the interlayer insulating film IL. The source electrode SE is embedded in the hole CH1. In addition, the source electrode SE is electrically connected to the source region NS, the body region PB, and the high concentration region PR, and supplies a source potential (fixed potential) to these regions.

As illustrated in the C-C cross section in FIGS. 3 and 5, the gate electrode GE includes a first end on the region 2A side and a second end on the region 2A′ side in the Y direction. A hole CH2 is formed in the interlayer insulating film IL. The hole CH2 on the region 2A side is formed so as to overlap the first end of the gate electrode GE in plan view, and the hole CH2 on the region 2A′ side is formed so as to overlap the second end of the gate electrode GE in plan view.

Note that “the first end of the gate electrode GE” described in the present specification is a portion of the gate electrode GE where the hole CH2 of the region 2A is provided, and is a portion adjacent to the body region PB where the source region NS is not formed as in the C-C cross section of FIG. 5. Similarly, “the second end of the gate electrode GE” described in the present specification is a portion of the gate electrode GE where the hole CH2 of the region 2A′ is provided, and is a portion adjacent to the body region PB where the source region NS is not formed as in the C-C cross section of FIG. 5.

The gate wiring GW is formed on the interlayer insulating film IL. The gate wiring GW is embedded in the hole CH2. The gate wiring GW is electrically connected to the gate electrode GE, and supplies a gate potential to the gate electrode GE.

As illustrated in the B-B cross sections of FIGS. 3 and 4 and the D-D cross section of FIG. 5, a part of the field plate electrode FP forms the contact portion FPa of the field plate electrode FP. The contact portion FPa is formed not only below the trench TR but also above the trench TR inside the trench TR located between the gate electrode GE on the region 2A side (first end side) and the gate electrode GE on the region 2A′ side (second end side).

The position of the upper surface of the insulating film IF1 in contact with the field plate electrode FP other than the contact portion FPa is lower than the position of the upper surface of the insulating film IF1 in contact with the contact portion FPa. That is, the position of the upper surface of the insulating film IF1 in the A-A cross section is located at a depth of, for example, 700 nm or more and 900 nm or less from the upper surface of the semiconductor substrate SUB. The position of the upper surface of the insulating film IF1 in the B-B cross section is located at a depth of, for example, 600 nm or more and 800 nm or less from the upper surface of the semiconductor substrate SUB.

In addition, the position of the upper surface of the contact portion FPa is higher than the position of the upper surface of the semiconductor substrate SUB, and is located at a height of, for example, 200 nm or more and 400 nm or less from the upper surface of the semiconductor substrate SUB.

A coupling portion GEa is formed on both side surfaces of the contact portion FPa via the insulating film IF2 in the X direction. The coupling portion GEa extends in the Y direction and connects the gate electrode GE on the region 2A side (first end side) to the gate electrode GE on the region 2A′ side (second end side). The gate electrode GE and the coupling portion GEa are made of an integrated n-type polycrystalline silicon film. Therefore, the gate potential is also supplied from the gate wiring GW to the coupling portion GEa. The coupling portion GEa is covered with the insulating film IF3.

The hole CH3 is formed in the interlayer insulating film IL. The hole CH3 is formed so as to overlap the contact portion FPa in plan view. The source electrode SE is embedded in the hole CH3. The source electrode SE is electrically connected to the field plate electrode FP, and supplies a source potential to the field plate electrode FP.

Additionally, the source electrode SE and the gate wiring GW are made of, for example, a barrier metal film and a conductive film formed on the barrier metal film. The barrier metal film is, for example, a titanium nitride film, and the conductive film is, for example, an aluminum film.

Note that the source electrode SE and the gate wiring GW may include a plug layer that fills the holes CH1 to CH3 and a wiring layer formed on the interlayer insulating film IL. In this case, the wiring layer includes the barrier metal film and the conductive film. The plug layer includes a barrier metal film such as a titanium nitride film and a conductive film such as a tungsten film.

Such a semiconductor device is referred to as a split gate type MOSFET.

FIG. 6 is a layout of trenches in the related semiconductor device. As illustrated in the upper view of FIG. 6, a plurality of layouts of trenches of the related semiconductor device are arranged in parallel in one direction in the semiconductor chip.

FIG. 7 is a view illustrating wafer warpage of the related semiconductor device. The wafer in FIG. 7 is a wafer in which trenches are arranged perpendicularly to a notch or an orientation flat. As illustrated in FIG. 7, the amount of warpage of the wafer is smallest at 0 degrees which is a direction perpendicular to the notch. Next, the amount of warpage at 45 degrees or 135 degrees with respect to the notch is large. The amount of warpage at 90 degrees with respect to the notch is the largest.

When the trench is disposed in parallel with the notch as described above, warpage in the left-and-right direction with respect to the notch increases. Therefore, there is a possibility that wafer conveyance or the like is affected and productivity is adversely affected.

In order to solve this problem, it is conceivable to form trenches in two vertical and horizontal directions in the semiconductor chip, as illustrated in the lower view of FIG. 6.

However, when it is attempted to form a transistor having the same area as that of the upper view of FIG. 6, the chip size is enlarged, and the productivity is lowered.

### Description of Semiconductor Device According to Embodiment

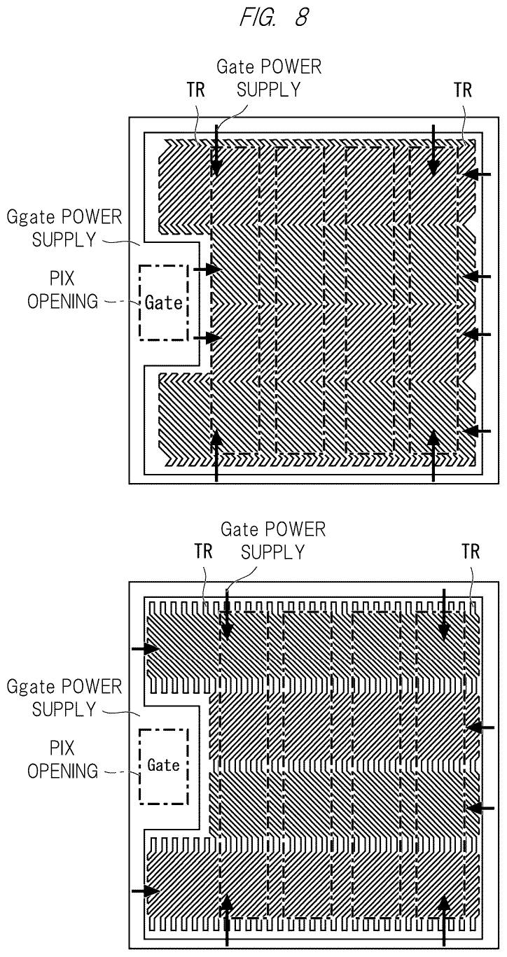

Therefore, a semiconductor device according to an embodiment provides a layout of trenches for controlling warpage of the wafer without deterioration in productivity. FIG. 8 is a layout of trenches of the semiconductor device according to the embodiment.

As illustrated upper view of FIG. 8, the semiconductor device according to the embodiment includes a trench formed in a first main surface of a semiconductor chip, in which the trench has a portion extending in a first direction and a portion extending in a second direction different from the first direction in a continuous manner in plan view. For example, a trench is formed in a diagonal direction with respect to the semiconductor chip. The first direction may be 45 degrees relative to the notch and the second direction may be 135 degrees.

In addition, as illustrated in the lower view of FIG. 8, the trench may have a portion extending in a third direction different from the first direction and the second direction, in which the portion is located between the portion extending in the first direction and the portion extending in the second direction in plan view. For example, the third direction may be 0 degrees relative to the notch. In this manner, the portion extending in the first direction intersects the portion extending in the third direction at an obtuse angle. Further, the portion extending in the second direction intersects the portion extending in the third direction at an obtuse angle.

The semiconductor device according to the embodiment may include a plurality of trenches, and a portion extending in the first direction and a portion extending in the second direction may be arranged in parallel to each other in the plurality of trenches. The plurality of trenches may not have a portion extending in the first direction and a continuous portion extending in the second direction in a continuous manner. In addition, the lengths of the trenches may be different. It is important that the portion extending in the first direction and the portion extending in the second direction are arranged in one semiconductor chip. Therefore, a plurality of transistors can be arranged. In addition, warpage of the wafer can be controlled without increasing the chip size.

Here, electrical properties of the semiconductor device will be considered. In the related semiconductor device, the reason why the trench is formed parallel to the notch is to make a channel of the trench MOSFET a {100} plane and improve the electrical characteristics using a silicon wafer having the surface in a {100} plane and the notch in a <100> direction.

When the trench is formed obliquely 45 degrees relative to the notch as in the semiconductor device according to the embodiment, a crystal plane of the first main surface is preferably {100}, the notch is preferably in a <110> direction, and the channel of the trench MOSFET is preferably a {100} plane. That is, in the semiconductor device according to the embodiment, it is preferable that the crystal plane of the first main surface is {100}, the first direction is an angle of 45 degrees when the notch or the orientation flat is viewed from a front side, and the second direction is an angle of 135 degrees when the notch or the orientation flat is viewed from the front side.

According to the present disclosure, it is possible to provide a semiconductor device capable of controlling warpage of a semiconductor chip and eventually a semiconductor wafer. In addition, there is provided a method for manufacturing a semiconductor device including a trench formed in a first main surface of a semiconductor chip, in which the trench has a portion extending in a first direction and a portion extending in a second direction different from the first direction in a continuous manner in plan view.

For example, the semiconductor device according to the above-described embodiment may have a configuration in which the conductivity type (p-type or n-type) of a semiconductor substrate, a semiconductor layer, a diffusion layer (diffusion region), or the like is inverted. Therefore, when one of the n-type and the p-type conductivity types is defined as the first conductivity type and the other conductivity type is defined as the second conductivity type, the first conductivity type can be defined as the p-type and the second conductivity type can be defined as the n-type, and conversely, the first conductivity type can be defined as the n-type and the second conductivity type can be defined as the p-type.

Although the invention made by the present inventors has been specifically described above based on embodiments, the present invention is not limited to the above-described embodiments, and it goes without saying that various modifications can be made without departing from the gist of the present invention.

What is claimed is:

1. A semiconductor device comprising a trench formed in a first main surface of a semiconductor chip, the trench having a portion extending in a first direction and a portion extending in a second direction different from the first direction in a continuous manner in plan view.

2. The semiconductor device according to claim 1,
wherein the trench has a portion extending in a third direction different from the first direction and the second direction, the portion extending in the third direction being located between the portion extending in the first direction and the portion extending in the second direction in plan view,
wherein the portion extending in the first direction intersects the portion extending in the third direction at an obtuse angle, and
wherein the portion extending in the second direction intersects the portion extending in the third direction at an obtuse angle.

3. The semiconductor device according to claim 1,
wherein the semiconductor device is a split gate type metal oxide semiconductor field effect transistor (MOSFET).

4. The semiconductor device according to claim 3,
wherein the trench has a field plate and a gate electrode formed therein.

5. The semiconductor device according to claim 1,
wherein a plurality of the trenches are provided, and
wherein, in the plurality of trenches, portions extending in the first direction are arranged in parallel to each other and portions extending in the second direction are arranged in parallel to each other.

6. The semiconductor device according to claim 1,
wherein a crystal plane of the first main surface is {100},
wherein a notch or an orientation flat is in a <110> direction,
wherein the first direction is an angle of 45 degrees when the notch or the orientation flat is viewed from a front side, and
wherein the second direction is an angle of 135 degrees when the notch or the orientation flat is viewed from the front side.

7. A method for manufacturing a semiconductor device, comprising forming a trench in a first main surface of a semiconductor chip, the trench having a portion extending in a first direction and a portion extending in a second direction different from the first direction in a continuous manner in plan view.

8. The method for manufacturing the semiconductor device according to claim 7,
wherein the trench has a portion extending in a third direction different from the first direction and the second direction, the portion extending in the third direction being located between the portion extending in the first direction and the portion extending in the second direction in plan view,
wherein the portion extending in the first direction intersects the portion extending in the third direction at an obtuse angle, and
wherein the portion extending in the second direction intersects the portion extending in the third direction at an obtuse angle.

9. The method for manufacturing the semiconductor device according to claim 7,
wherein the semiconductor device is a split gate type metal oxide semiconductor field effect transistor (MOSFET).

10. The method for manufacturing the semiconductor device according to claim 9,
wherein the trench has a field plate and a gate electrode formed therein.

11. The method for manufacturing the semiconductor device according to claim 7,
wherein a plurality of the trenches are provided, and
wherein, in the plurality of trenches, portions extending in the first direction are arranged in parallel to each other and portions extending in the second direction are arranged in parallel to each other.

12. The method for manufacturing the semiconductor device according to claim 7,
wherein a crystal plane of the first main surface is {100},
wherein a notch or an orientation flat is in a <110> direction,
wherein the first direction is an angle of 45 degrees when the notch or the orientation flat is viewed from a front side, and
wherein the second direction is an angle of 135 degrees when the notch or the orientation flat is viewed from the front side.
